(19) United States
(12) Patent Application Publication
(10) Pub. No.: US 2006/0015795 A1
(43) Pub. Date: Jan. 19, 2006

(54) Audio data processor

(75) Inventors: Manabu Miura, Tokyo (JP); Nobuyuki Fujii, Tokyo (JP); Yoshifumi Hanamoto, Hyogo (JP); Yoshiyuki Osako, Hyogo (JP)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Renesas Technology Corp., Tokyo (JP)

(21) Appl. No.: 11/171,321

(22) Filed: Jul. 1, 2005

(30) Foreign Application Priority Data
Jul. 15, 2004 (JP) 2004-208614

(51) Int. Cl. H03M 13/00

(52) U.S. Cl. 714/776

(57) ABSTRACT

An audio data processor includes a packet receiver for receiving audio data packets and a coded data extractor for extracting coded data from the received packets. When an error detector detects a receiving error of a packet in the packet receiver, a data interpolator generates interpolation coded data on the basis of coded data of a packet normally received immediately before the missing packet, and interpolates coded data of the missing packet by the interpolation coded data.

### BACKGROUND OF THE INVENTION

1. Field of the Invention

The present invention relates to an audio data processor, and more particularly, to a technique for preventing abnormal noise from occurring due to a packet receiving error while reproducing audio data on the basis of a stream of received audio data packets.

2. Description of the Background Art

Generally, in a digital communication system for transmitting audio data, a device at the transmitting end encodes digital audio data (linear data) into coded data, divides the coded data into packets (audio data packets) in a certain unit, and transmits the audio data packets. A device at the receiving end performs a series of processing of extracting the coded data from received packets, decoding the coded data into original digital linear data, and successively reproducing the original digital linear data upon performing D/A conversion thereon. In such a system, when a packet is lost due to an error occurred while packet transmission, data of the missing packet is output as abnormal noise at the time of reproduction.

As a technique for preventing abnormal noise from occurring due to such packet loss, interpolation has conventionally been conducted in which linear data of a missing packet is interpolated by, e.g., linear interpolation on the basis of a value of linear data of a preceding packet received immediately before the missing packet and a value of linear data of a succeeding packet received immediately after the missing packet. Since the interpolated linear data takes gently varying values, an audio signal reproduced upon performing D/A conversion on the linear data presents a smooth waveform, which prevents abnormal noise from occurring.

With this technique, however, obtaining linear data for interpolating the missing packet requires linear data of the succeeding packet received immediately after the missing packet, which can only be obtained after coded data of the succeeding packet is decoded into linear data. Accordingly, with this technique, a time lag not less than the sum of the time required for receiving one packet and the time required for data processing for obtaining linear data of the received packet needs to be previously provided between the receipt of one packet and the generation of linear data of the received packet. Therefore, this technique is not suitable for audio communications, video communications or the like in which audio data of received packets needs to be reproduced in real-time.

Japanese Patent Application Laid-Open No. 2003-348023 discloses another technique for interpolating linear data of a missing packet by performing linear interpolation between linear data (called a “digital word” in the above-mentioned document) of a preceding packet received immediately before the missing packet and a predetermined value, without using linear data of a succeeding packet received immediately after the missing packet.

The above two techniques both require a computing operation such as linear interpolation, resulting in complicated circuit configuration. Further, since interpolation for a missing packet is performed on decoded linear data, the number of bits of data used for the computing operation is so large that a circuit for performing the computing operation is increased in size.

### SUMMARY OF THE INVENTION

An object of the present invention is to provide an audio data processor capable. of preventing abnormal noise resulting from loss of an audio data packet as well as reproducing audio data with a short time lag while preventing the circuit from being increased in complexity and size.

An audio data processor according to a first aspect of the invention includes a receiver for receiving packets containing coded data obtained by encoding audio linear data, and a coded data obtaining section for obtaining the coded data from the packets received by the receiver. The coded data obtaining section includes a detector for detecting a missing packet in the packets received by the receiver, and a data interpolator for interpolating coded data of the missing packet. The data interpolator interpolates the coded data of the missing packet, when detected by the detector, by interpolation coded data generated on the basis of coded data of a preceding packet normally received immediately before the missing packet. When the encoding is performed in one of A-law and μ-law formats, it is preferable that the interpolation coded data should only contain the last value of coded data of the preceding packet.

Abnormal noise resulting from packet loss is prevented from occurring. Since there is no need to wait until a succeeding packet immediately after the missing packet is received for generating the interpolation coded data, the time lag between the receipt and reproduction of a packet can be reduced, making the system suitable for real-time reproduction of audio data of received packets. Further, interpolation for the missing packet is performed on coded data yet to be decoded having a small number of bits, which prevents a circuit for performing the interpolation from being increased in size.

An audio data processor according to a second aspect of the invention includes a receiver for receiving packets containing coded data obtained by encoding audio linear data under the Continuous Variable Slope Delta scheme, and a coded data obtaining section for obtaining the coded data from the packets received by the receiver. The coded data obtaining section includes a detector for detecting a missing packet in the packets received by the receiver, and a data interpolator for interpolating coded data of the missing packet. The data interpolator interpolates the coded data of the missing packet, when detected by the detector, by interpolation coded data containing “0” and “1” repeated alternately.

Abnormal noise resulting from packet loss is prevented from occurring. Since generation of the interpolation coded data requires no complicated computing operation such as linear interpolation, the circuit can be prevented from becoming complicated, and the audio data processor can be manufactured compactly at low costs. Further, since there is no need to wait until a succeeding packet immediately after the missing packet is received for generating the interpolation coded data, the time lag between the receipt and reproduction of a packet can be reduced, making the system suitable for real-time reproduction of audio data of received packets. Furthermore, interpolation for the missing packet is performed on coded data yet to be decoded having a small number of bits, which prevents a circuit for performing the interpolation from being increased in size.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing the configuration of an audio data processor according to a first preferred embodiment of the present invention;

FIG. 2 is a flowchart showing an operation of the audio data processor according to the first preferred embodiment;

FIG. 3 is a timing chart showing an operation when packets are received normally in the audio data processor according to the first preferred embodiment;

FIG. 4 is a timing chart showing an operation when packet loss occurs in the audio data processor according to the first preferred embodiment;

FIG. 5 is a block diagram showing the configuration of an audio data processor according to a second preferred embodiment of the invention;

FIG. 6 is a flowchart showing an operation of the audio data processor according to the second preferred embodiment;

FIG. 7 is a flowchart showing data control in the second preferred embodiment;

FIG. 8 is a timing chart showing an operation when packet loss occurs in the audio data processor according to the second preferred embodiment;

FIG. 9 is a block diagram showing the configuration of an audio data processor according to a third preferred embodiment of the invention;

FIG. 10 is a flowchart showing an operation of the audio data processor according to the third preferred embodiment; and

FIG. 11 is a timing chart showing an operation when packet loss occurs in the audio data processor according to the third preferred embodiment.

### DESCRIPTION OF THE PREFERRED EMBODIMENTS

First Preferred Embodiment

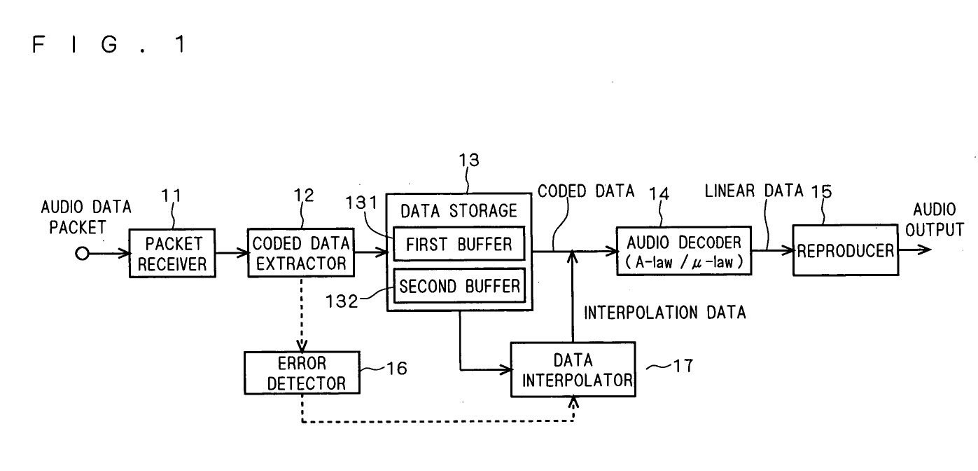

FIG. 1 is a block diagram showing the configuration of an audio data processor according to a first preferred embodiment of the present invention. As shown, the audio data processor includes a packet receiver 11, a coded data extractor 12, a data storage 13, an audio decoder 14, a reproducer 15, an error detector 16 and a data interpolator 17. The packet receiver 11 receives audio data packets sent from a device at the transmitting end. An audio data packet is a data packet (hereinafter simply referred to as a “packet” as well) containing coded data obtained by encoding digital audio data (linear data). The coded data extractor 12 removes a header portion which stores predetermined control information (e.g., destination address, sender address, etc.) from each packet received by the packet receiver 11 to extract coded data of audio data. The data storage 13 has two buffer memories (a first buffer 131 and a second buffer 132), and temporarily stores coded data extracted by the coded data extractor 12. The audio decoder 14 successively reads the coded data stored in the data storage 13 and decodes the coded data into original linear data. The reproducer 15 performs signal processing such as D/A conversion on the linear data output from the audio decoder 14 to reproduce audio.

The error detector 16 checks the coded data extracted by the coded data extractor 12 for errors to judge whether or not packets are normally received by the packet receiver 11 and to detect a missing packet, if any. In the case where the error detector 16 detects a missing packet, the data interpolator 17 reads coded data of a preceding packet normally received immediately before the missing packet and generates predetermined interpolation coded data on the basis of the coded data of the preceding packet, thereby interpolating coded data of the missing packet. That is, the coded data extractor 12, error detector 16 and data interpolator 17 constitute a coded data obtaining section for obtaining coded data to be reproduced.

In the present embodiment, coded data contained in received packets is encoded in either A-law or μ-law format. The audio decoder 14 shall perform decoding in either A-law or μ-law format, correspondingly.

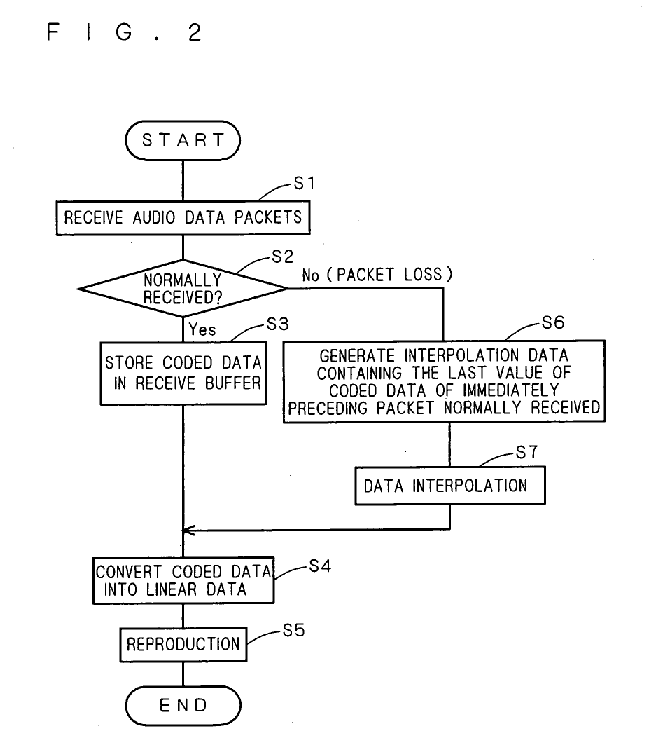

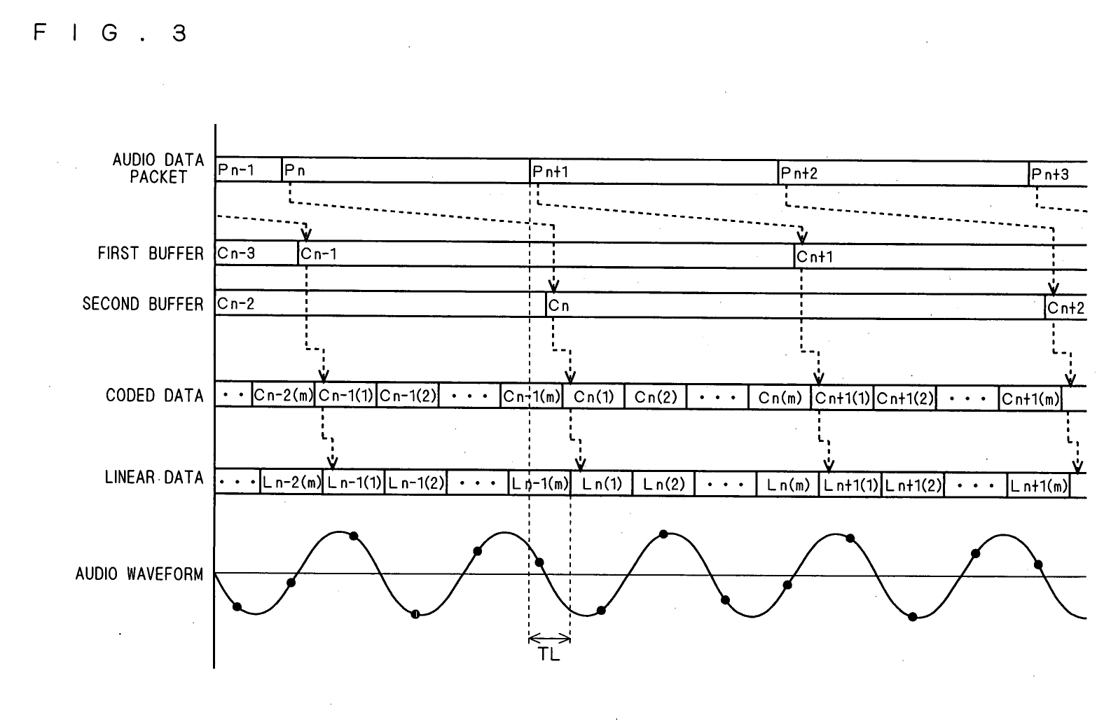

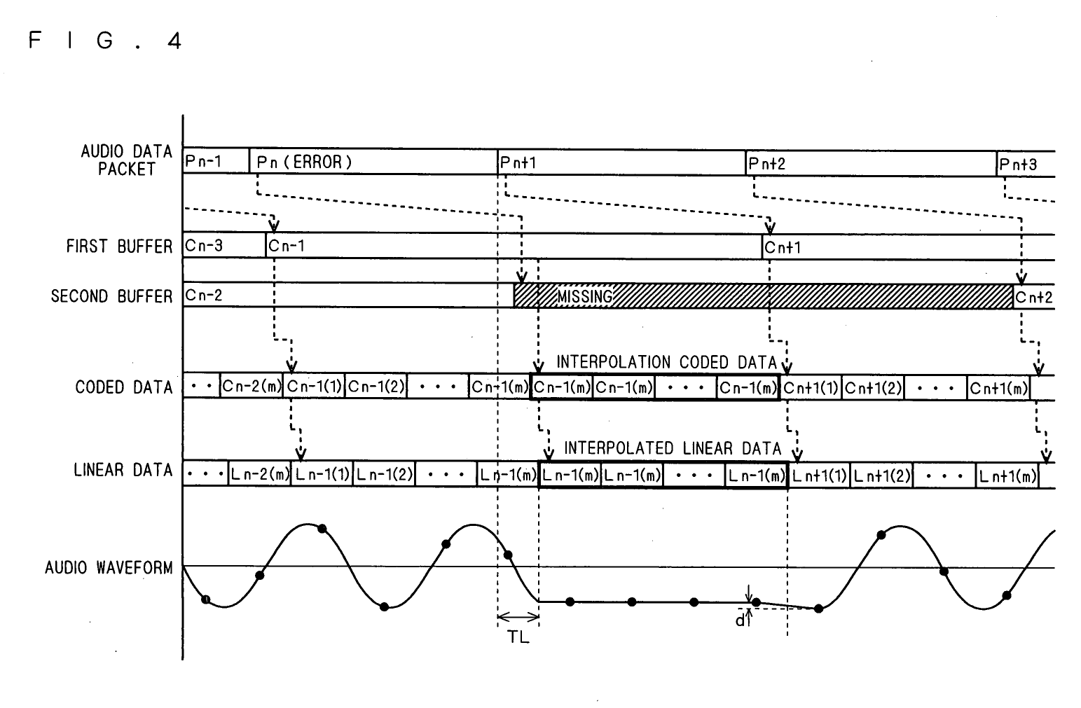

FIG. 2 is a flowchart showing an operation of the audio data processor according to the first preferred embodiment. FIGS. 3 and 4 are timing charts each showing an operation of the audio data processor. FIG. 3 shows the case where packets are normally received, and FIG. 4 shows the case where packet loss occurs. An operation of the audio data processor according to the present embodiment will be described now referring to these drawings.

When audio data packets are received by the packet receiver 11, the coded data extractor 12 extracts coded data of audio data from the received packets (S1). The error detector 16 checks the coded data for errors to judge whether or not the packets are normally received by the packet receiver 11 (S2).

First, an operation in the case where packets are normally received will be described. When packets are normally received, the coded data extractor 12 stores extracted coded data in the data storage 13 (S3). As shown in FIG. 1, the data storage 13 has the first buffer 131 and second buffer 132, and the coded data extractor 12 stores each packet of coded data alternately in the two buffers. For instance, coded data of odd-numbered packets is stored in the first buffer 131, and coded data of even-numbered packets is stored in the second buffer 132. More specifically, as shown in FIG. 3, when coded data Cn of an n-th packet Pn is stored in the second buffer 132, then, coded data Cn+1 of an (n+1)-th packet Pn+1 is stored in the first buffer 131, and coded data Cn+2 of an (n+2)-th packet Pn+2 is stored in the second buffer 132. One packet Pn contains a continuous stream of m pieces of coded data Cn(1) to Cn(m).

The audio decoder 14 successively reads coded data stored in the data storage 13 and decodes the coded data into original linear data (S4). As described above, coded data of each packet is stored in the first buffer 131 and second buffer 132 alternately; in the example of FIG. 3, when converting the coded data Cn of the n-th packet Pn into linear data, for example, a stream of coded data Cn(1) to Cn(m) is successively read from the second buffer 132 and is converted into linear data Ln(1) to Ln(m), respectively. When converting the coded data Cn+1 of the (n+1)-th packet Pn+1 into linear data, for example, a stream of coded data Cn+1(1) to Cn+1(m) is successively read from the first buffer 131 and is converted into linear data Ln+1(1) to Ln+1(m), respectively.

Linear data obtained by the audio decoder 14 is sent to the reproducer 15. The reproducer 15 performs predetermined signal processing such as D/A conversion on the linear data, thereby reproducing audio corresponding to the linear data (S5). Accordingly, an audio output is obtained with an analog waveform as shown in the lowermost part of FIG. 3.

The above-described processing is performed successively for each packet, so that audio corresponding to a stream of packets is continuously output. The time TL from the end of receiving a packet to the start of outputting audio corresponding to the packet is the time required for data processing only.

Described next is an operation in the case where packets are not received normally by the packet receiver 11 due to an error, resulting in packet loss. In this case, the error detector 16 detects a receiving error, that is, packet loss in step S2 of the flowchart shown in FIG. 2. For instance, as illustrated in FIG. 4, when an error occurs while receiving the n-th packet Pn to cause the packet Pn to get lost, the coded data Cn corresponding to the packet Pn goes missing in the data storage 13 (second buffer 132). In this case, data different from normal coded data Cn is stored in the second buffer 132, and produces abnormal noise in output audio reproduced through the audio decoder 14 and reproducer 15.

When the error detector 16 detects packet loss, the data interpolator 17 generates predetermined interpolation coded data for interpolating coded data of the missing packet (S6). In the present embodiment, interpolation coded data is generated on the basis of coded data of a preceding packet normally received immediately before the missing packet. More specifically, the interpolation coded data only contains the last value of coded data of the preceding packet. That is, the data interpolator 17 reads the last value of coded data of the preceding packet from the data storage 13, to generate interpolation coded data only containing that value for interpolating one packet. For instance, when the packet Pn is missing as shown in FIG. 4, the data interpolator 17 reads the last value Cn−1(m) of coded data. of the preceding packet Pn−1 normally received immediately before the missing packet Pn from the first buffer 131, to generate interpolation coded data only containing the value Cn−1(m).

Then, the data interpolator 17 sends the generated interpolation coded data to the audio decoder 14, thereby interpolating coded data of the missing packet (S7). The audio decoder 14 normally reads coded data from the data storage 13 and decodes the coded data as described above, however, when the interpolation coded data is interpolated by the data interpolator 17, the audio decoder 14 decodes the interpolation coded data (S4). As a result, as shown in FIG. 4, the coded data Cn of the missing packet Pn is apparently replaced by the interpolation coded data only containing the last value Cn−1(m) of coded data of the preceding packet Pn−1.

In the present embodiment, as described above, the audio decoder 14 performs decoding in either A-law or μ-law format. In either format, values of coded data have a one-to-one correspondence with values of linear data obtained by decoding coded data. Accordingly, linear data corresponding to the interpolation coded data only containing the constant value Cn−1(m) (hereinafter referred to as “interpolated linear data”) shall only contain a constant value Ln−1(m) (the last value of linear data of the preceding packet Pn−1), as shown in FIG. 4.

The linear data obtained by the audio decoder 14 is subjected to predetermined signal processing such as D/A conversion in the reproducer 15, and is reproduced as audio (S5). Since the linear data of the missing packet Pn (interpolated linear data) continuously takes the constant value Ln−1(m), output audio in that portion presents a flat waveform as shown in FIG. 4, which is nearly silent. In summary, abnormal noise due to packet loss is prevented from occurring.

Further, the interpolation coded data is generated only on the basis of coded data of the preceding packet normally received immediately before the missing packet, which eliminates the need to wait until the succeeding packet immediately after the missing packet is received. Accordingly, the time TL from the end of receiving a packet to the start of outputting audio corresponding to the packet is the time required for data processing only.

According to the present embodiment as described above, when packet loss occurs, missing coded data is interpolated by predetermined interpolation coded data, making it possible to prevent abnormal noise from occurring. To generate the predetermined interpolation coded data, there is no need to wait until the succeeding packet immediately after the missing packet is received. Therefore, the time lag between the receipt and reproduction of a packet can be shortened, making the system suitable for real-time reproduction of audio data of received packets.

Further, interpolation for the missing packet. is performed on coded data yet to be decoded having a small number of bits, which prevents a circuit for performing the interpolation from being increased in size. Since the interpolation coded data is generated using a certain value of coded data of a packet stored in the data storage 13 without any complicated computing operation such as linear interpolation, the circuit is prevented from becoming complicated. Therefore, the audio data processor can be manufactured compactly at low costs.

This preferred embodiment has described the configuration in which the interpolation coded data is directly input to the audio decoder 14 from the data interpolator 17, but may be input to the audio decoder 14 through the data storage 13. More specifically, the audio data processor may be configured such that the data interpolator 17 temporarily stores the interpolation coded data in an area corresponding to the missing packet (the hatched portion of the second buffer in FIG. 4) in the data storage 13, and the audio decoder 14 reads the interpolation coded data. In that case, when packet loss occurs, the audio decoder 14 may operate in the same manner as in the case where packets are received normally. Therefore, the audio decoder 14 can be simplified in construction.

In the configuration according to the present embodiment, the data storage 13 has the two buffers, i.e., the first buffer 131 and second buffer 132, and each packet of coded data is stored alternately in the two buffers. Accordingly, coded data of an immediately preceding packet always remains in the data storage 13, which brings about an advantage in that coded data of the preceding packet can easily be used when generating the interpolation coded data of the missing packet. Further, the number of buffers may be three or more, or alternatively, another memory for always storing coded data of an immediately preceding packet may be provided. The same advantage is brought about in either case.

The present embodiment employs either A-law or μ-law format in encoding/decoding, however, any other method that makes values of coded data and values of linear data obtained by decoding the coded data have a one-to-one correspondence may be employed.

Second Preferred Embodiment

In the first preferred embodiment, the interpolated linear data of the missing packet only contains the last value of normal linear data of the preceding packet (linear data of a normally-received packet). Thus, as shown in FIG. 4, the interpolated linear data continues smoothly to the preceding normal linear data at the border therebetween. In contrast, the interpolated linear data does not always continue smoothly to the succeeding normal linear data, which may cause a difference (“d” in FIG. 4) therebetween. When this difference d is great, abnormal noise occurs in that portion. Therefore, the present embodiment will propose a technique for controlling abnormal noise from occurring at the border between interpolated linear data and succeeding normal linear data.

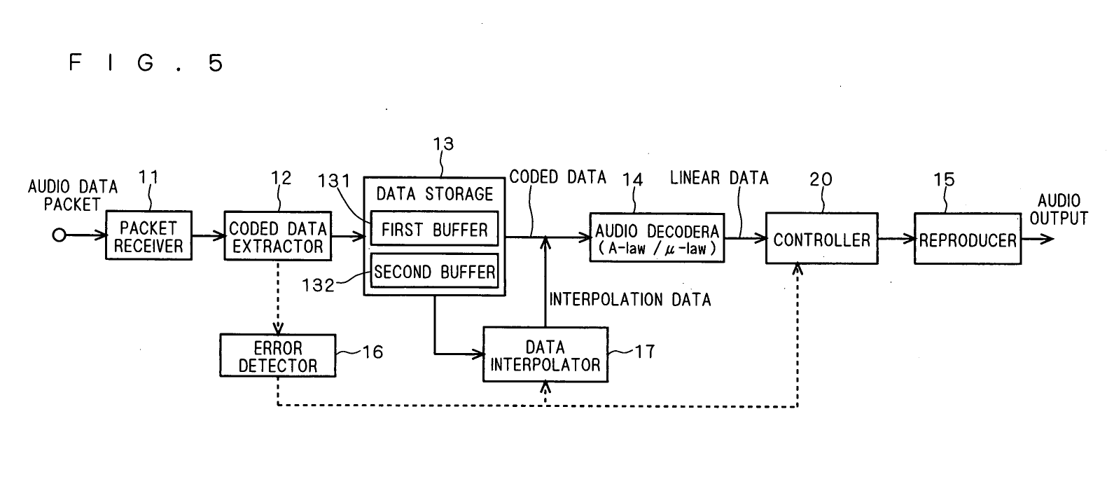

FIG. 5 is a block diagram showing the configuration of an audio data processor according to a second preferred embodiment. In this drawing, components having the same functions as those shown in FIG. 1 are indicated by the same reference numerals. The only difference from the configuration shown in FIG. 1 is a controller 20 for controlling decoded linear data. The controller 20 controls input linear data to maintain the interpolated linear data until the difference between the interpolated linear data and succeeding normal linear data falls below a predetermined value. The configuration except the controller 20 is the same as that of FIG. 1, and repeated explanation is thus omitted here.

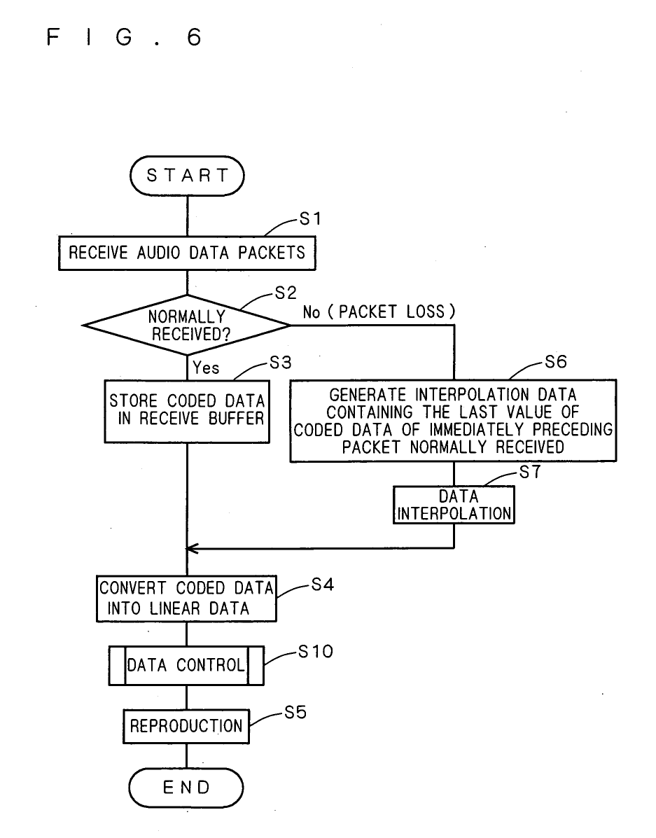

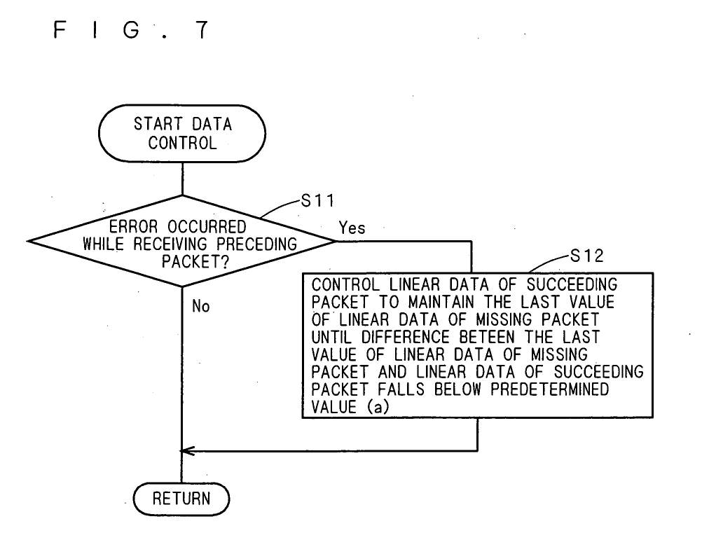

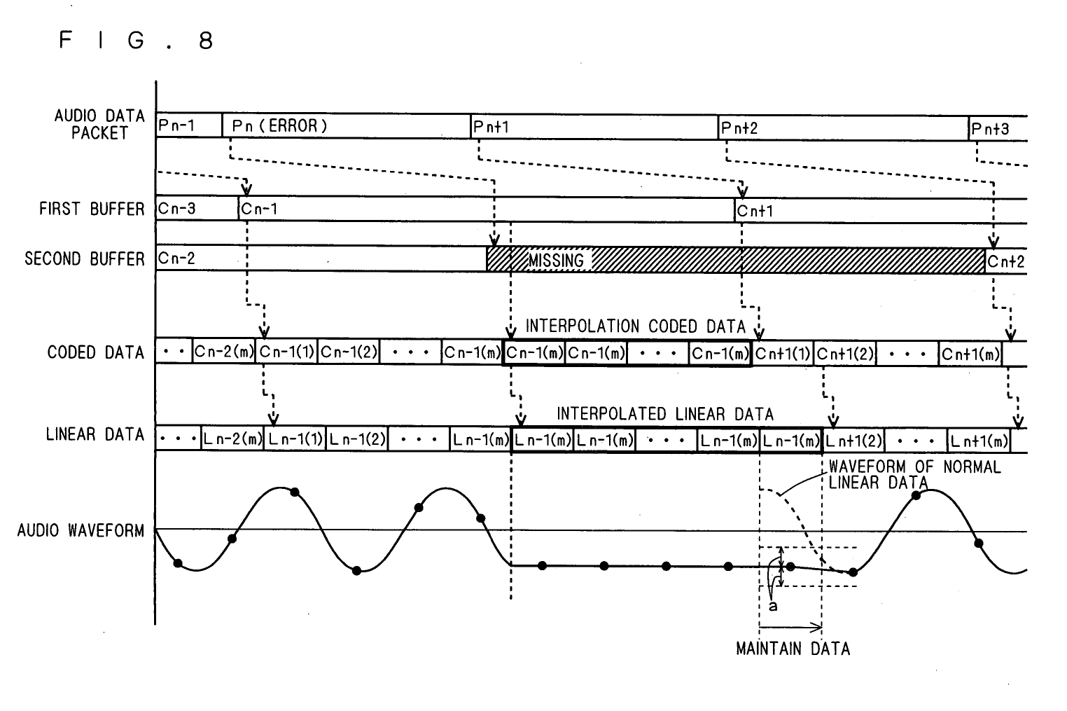

FIGS. 6 and 7 are flowcharts each showing an operation of the audio data processor according to the second preferred embodiment. FIG. 8 is a timing chart showing an operation when packet loss occurs in the audio data processor.

In the present embodiment, as shown in FIG. 6, step S10 of controlling linear data is conducted prior to step S5 of reproducing audio corresponding to the linear data. The operation except the step S10 is the same as in the first preferred embodiment, and repeated explanation is thus omitted here.

FIG. 7 is a flowchart showing data control in step S10. As shown, in step S10, it is first checked whether or not an error has occurred while receiving a preceding packet.

When the preceding packet has normally been received, linear data currently being reproduced is normal linear data. In this case, the problem of abnormal noise at the border between the interpolated linear data and succeeding normal linear data does not arise, and the process proceeds into step S5.

When an error has occurred while receiving a preceding packet, linear data currently being reproduced is interpolated linear data. In this case, abnormal noise may occur at the border between the interpolation linear data currently being reproduced and linear data of the succeeding packet received immediately after the missing packet. Then, the linear data of the succeeding packet is controlled to maintain the last value of linear data of the missing packet (which corresponds to the interpolated linear data) until the difference between the last value of the interpolated linear data and the linear data of the succeeding packet falls below a predetermined value (“a” in FIG. 8). More specifically, when the packet Pn is missing as shown in FIG. 8, normal linear data of the succeeding packet Pn+1 is controlled to maintain the value Ln−1(m) of the interpolated linear data of the missing packet Pn until the difference between the value Ln−1(m) and the value Ln+1(i) (i=1, 2, . . . , m) of the linear data of the succeeding packet Pn+1 falls below the predetermined value “a”. As a result, the interpolated linear data of the missing packet Pn continues smoothly to the linear data of the succeeding packet Pn+1.

Accordingly, the reproducer 15 maintains and reproduces the interpolated linear data of the missing packet until the normal linear data of the succeeding packet approaches the last value of the interpolated linear data at the border between the interpolated linear data and normal linear data of the succeeding packet. Once the normal linear data of the succeeding packet approaches the last value of the interpolated linear data, the normal linear data is reproduced thereafter.

In the present embodiment, as described above, linear data is controlled such that the interpolated linear data of the missing packet continues smoothly to the normal linear data of the succeeding packet, which prevents abnormal noise from occurring at the border therebetween.

As the predetermined value “a” decreases, abnormal noise in audio output can be made lower, however, when the value “a” is too small, the period in which the interpolated linear data is maintained (i.e., a silent period) is extended. Therefore, it is preferable that the value “a” should be large to a certain degree.

Third Preferred Embodiment

The first preferred embodiment employs either A-law or μ-law format in encoding/decoding. In contrast, the present embodiment applies the invention to a system employing the CVSD (Continuous Variable Slope Delta) encoding/decoding scheme.

In CVSD encoding, a current value of linear data is compared with a preceding value of linear data, and “0” is output when the current value is greater than the preceding value, and otherwise, “1” is output. Coded data is thereby generated. In CVSD decoding, coded data indicating “0” or “1” is decoded into linear data by increasing amplitude by a predetermined value in the case of “0” and by decreasing amplitude by a predetermined value in the case of “1”.

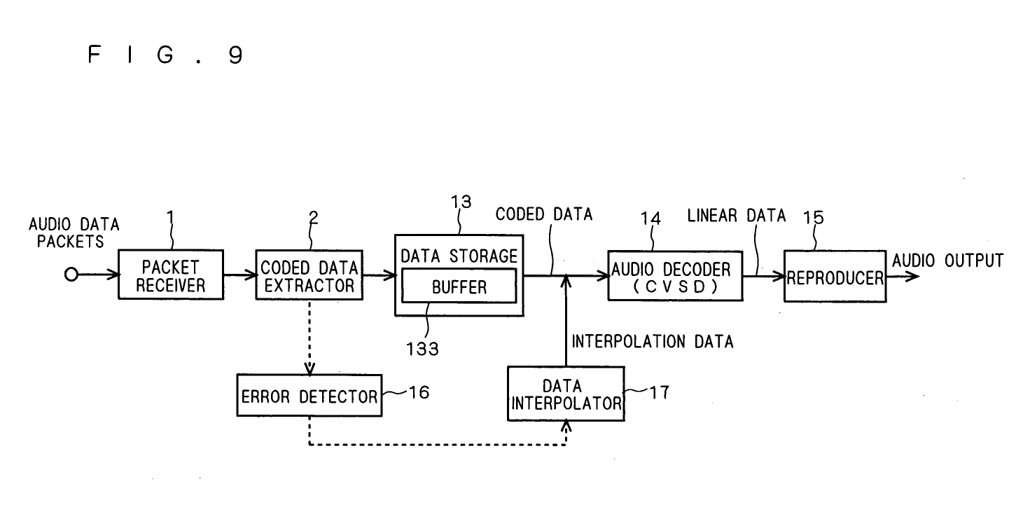

FIG. 9 is a block diagram showing the configuration of an audio data processor according to a third preferred embodiment. In this drawing, components having the same functions as those shown in FIG. 1 are indicated by the same reference numerals. The audio data processor according to this embodiment differs from that of FIG. 1 in that the audio decoder 14 performs CVSD decoding and that the interpolation coded data generated by the data interpolator 17 contains “0” and “1” repeated alternately (i.e., “010101 . . . 010101” or “101010 . . . 101010”).

In the audio data processor according to the first preferred embodiment, the interpolation coded data is generated by using the preceding coded data, and therefore, the data storage 13 is provided with the two buffers, i.e., first buffer 131 and second buffer 132 such that coded data of an immediately preceding packet always remains in the data storage 13. In contrast, according to the present embodiment, the interpolation coded data simply contains “0” and “1” repeated alternately, so that coded data of the preceding packet is not required for generating the interpolation coded data. Therefore, as shown in FIG. 9, the data storage 13 according to the present embodiment is provided with a single buffer 133.

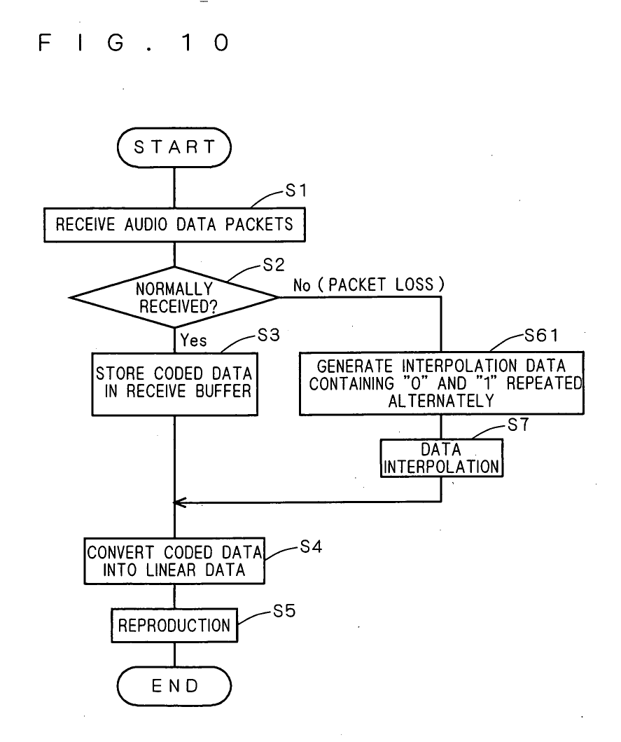

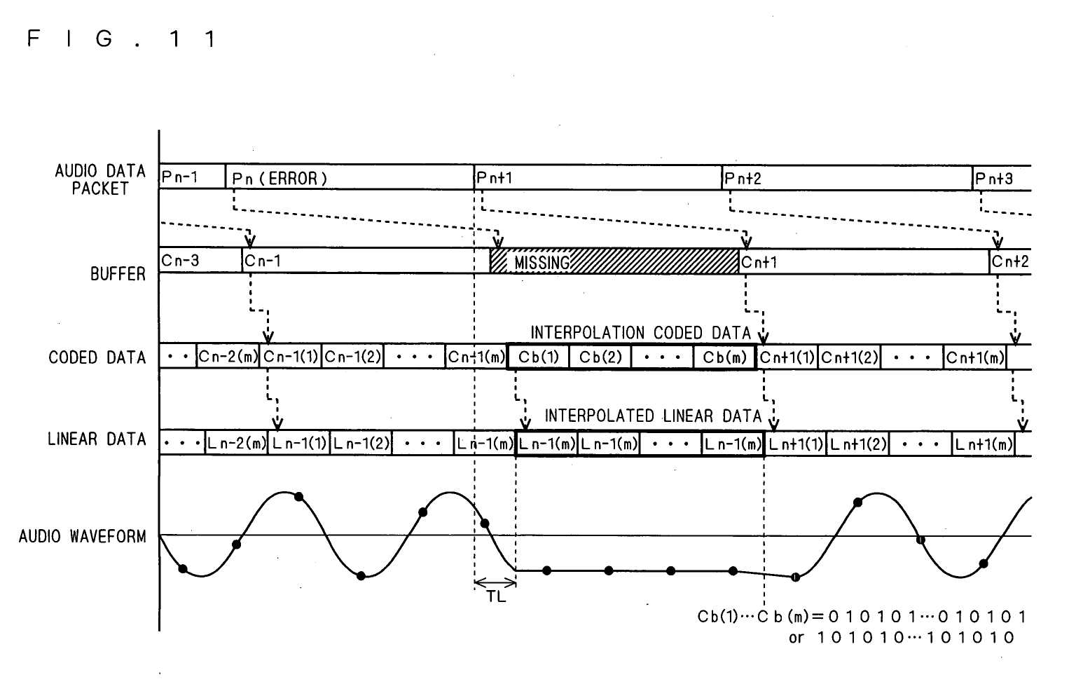

FIG. 10 is a flowchart showing an operation of the audio data processor according to the third preferred embodiment. FIG. 11 is a timing chart showing an operation when packet loss occurs in the audio data processor.

In the present embodiment, as shown in FIG. 10, step S6 shown in FIG. 2 is replaced by step S61 in which the data interpolator 17 generates interpolation coded data containing “0” and “1” repeated alternately. Further, step S4 of converting coded data into linear data is executed by CVSD decoding. Other steps are the same as those in the flowchart of FIG. 2.

Accordingly, when the packet Pn goes missing as shown in FIG. 11 due to an error in the present embodiment, interpolation coded data Cb(1) to Cb(m) in which “0” and “1” are repeated alternately is interpolated as coded data corresponding to the missing packet Pn. As described above, in CVSD decoding, linear data is obtained by increasing amplitude by a predetermined value in the case of “0” and by decreasing amplitude by a predetermined value in the case of “1”. Therefore, interpolated linear data obtained by decoding the interpolation coded data Cb(1) to Cb(m) shall only contain values close to the last value Ln−1(m) of linear data of the preceding packet (in FIG. 11, all values of the interpolated linear data are indicated as “Ln−1(m)” for ease of illustration.) Since the interpolated linear data corresponding to the missing packet continuously takes values close to the constant value Ln−1(m), output audio in that portion presents a flat waveform as shown in FIG. 11, which is nearly silent. That is, abnormal noise resulting from packet loss is prevented from occurring.

Since the interpolation coded data simply contains “0” and “1” repeated alternately, there is no need to wait until the succeeding packet immediately after the missing packet is received. Accordingly, the time TL from the end of receiving a packet to the start of outputting audio corresponding to the packet is the time required for data processing only, similarly to the first preferred embodiment.

In the present embodiment, as described above, when packet loss occurs, coded data of the missing packet is interpolated by predetermined interpolation coded data. Abnormal noise resulting from packet loss is thus prevented from occurring. To generate the interpolation coded data, there is no need to wait until the succeeding packet is received. Therefore, the time lag between the receipt and reproduction of a packet is reduced, making the system suitable for reproducing audio data of received packets in real-time.

Further, interpolation for the missing packet is performed on coded data yet to be decoded having a small number of bits, which prevents a circuit for performing the interpolation from being increased in size. Since generation of the interpolation coded data requires no complicated computing operation such as linear interpolation, the circuit is prevented from becoming complicated, which allows the audio data processor to be manufactured compactly at low costs.

This preferred embodiment has described the configuration in which the interpolation coded data is directly input to the audio decoder 14 from the data interpolator 17, but may be input to the audio decoder 14 through the data storage 13. More specifically, the audio data processor may be configured such that the data interpolator 17 temporarily stores the interpolation coded data in the buffer 133 of the data storage 13 (the hatched portion of the buffer in FIG. 11) and the audio decoder 14 reads the interpolation coded data. In that case, when packet loss occurs, the audio decoder 14 may operate in the same manner as in the case where packets are received normally. Therefore, the audio decoder 14 can be simplified in construction.

The present embodiment employs the CVSD encoding/decoding scheme, however, any other delta modulation method that expresses a difference of linear data in amplitude by 1 bit may be employed.

While the invention has been shown and described in detail, the foregoing description is in all aspects illustrative and not restrictive. It is therefore understood that numerous modifications and variations can be devised without departing from the scope of the invention.

What is claimed is:

1. An audio data processor comprising:
a receiver for receiving packets each containing coded data obtained by encoding audio linear data; and
a coded data obtaining section for obtaining said coded data from said packets received by said receiver, wherein
said coded data obtaining section includes:
a detector for detecting a missing packet from said packets received by said receiver; and
a data interpolator for interpolating coded data of said missing packet, when detected by said detector, by interpolation coded data generated on the basis of coded data of a preceding packet normally received immediately before said missing packet.

2. The audio data processor according to claim 1, wherein
said encoding is performed in one of A-law and μ-law formats, and
said interpolation coded data only contains the last value of coded data of said preceding packet.

3. The audio data processor according to claim 2, further comprising:
a decoder for decoding said coded data into original audio linear data; and
a data controller for controlling said audio linear data as decoded, wherein
said data controller controls said decoded audio linear data to maintain the value of audio linear data obtained from said interpolation coded data until the difference between said audio linear data obtained from said interpolation coded data and audio linear data obtained from a succeeding packet normally received after said missing packet falls below a predetermined value.

4. The audio data processor according to claim 2, further comprising
a plurality of receive buffers for temporarily storing coded data obtained from packets normally received.

5. An audio data processor comprising:
a receiver for receiving packets each containing coded data obtained by encoding audio linear data under the Continuous Variable Slope Delta scheme; and
a coded data obtaining section for obtaining said coded data from said packets received by said receiver, wherein
said coded data obtaining section includes:
a detector for detecting a missing packet from said packets received by said receiver; and
a data interpolator for interpolating coded data of said missing packet, when detected, by said detector, by interpolation coded data containing “0” and “1” repeated alternately.
